(19) United States
(12) Patent Application Publication
(10) Pub. No.: US 2017/0330980 A1
(43) Pub. Date: Nov. 16, 2017

(54) DIE REPATTERNING TRANSMISSION LINES ON SILICON PHOTOMULTIPLIERS

(71) Applicant: General Electric Company, Schenectady, NY (US)

(72) Inventors: James Wilson ROSE, Guilderland, NY (US); David Leo McDANIEL, Dousman, WI (US); Sergei Ivanovich DOLINSKY, Clifton Park, NY (US); Sabarni PALIT, Niskayuna, NY (US)

(21) Appl. No.: 15/155,507

(22) Filed: May 16, 2016

(51) Int. Cl. H01L 31/02; H01L 31/107; H01L 31/028; H01L 31/18; H01L 27/144

(52) U.S. Cl. CPC H01L 31/02005; H01L 31/1804; H01L 27/1443; H01L 31/028; H01L 31/107

(57) ABSTRACT

A silicon photomultiplier array includes a plurality of microcells within the photomultiplier array and located on the silicon wafer, the plurality of microcells arranged in rows and columns, each of the plurality of microcells including an output port, and configured to provide a pulse waveform having pulse characteristics, at least one repatterning dielectric layer in contact with a silicon wafer layer back surface, the silicon wafer having an active surface opposed to the back surface, and a plurality of respective through-silicon-vias (TSVs) coupling the output port of respective ones of the plurality of microcells on the active surface of the silicon wafer to a plurality of respective circuit traces on the at least one repatterning dielectric layer disposed on the back surface of the silicon wafer. A method for producing the silicon photomultiplier array is also disclosed.

### BACKGROUND

Radiation detection approaches exist that employ photosensors incorporating a microcell (e.g., a single photon avalanche diode (SPAD)) operating in Geiger mode. Certain of these approaches have been implemented in large area devices, such as may be used in nuclear detectors. A readout pixel can be made up of an array of microcells, where each individual microcell can be connected to a readout network via a quenching resistor exhibiting resistance between 100 kΩ to 1 MΩ, known as solid state photomultiplier (SSPM), silicon photomultipliers (SiPM), multi-pixel photon counting (MPPC). When a bias voltage applied to the silicon photomultiplier (SiPM) is above breakdown, a detected photon generates an avalanche, the APD capacitance discharges to a breakdown voltage and the recharging current creates a signal.

Typically, the pulse shape associated with a single photo electron (SPE) signal has a fast rise time, followed by a long fall time. When detecting fast light pulse (e.g., on the order of tens of nanoseconds) such signals are aggregated across the numerous microcells forming a pixel of a SiPM device. The resulting pulse shape of the summed signal has a slow rise time (e.g., in the tens of nanoseconds) due to the convolution of single microcell responses with detected light pulse. Therefore, it is difficult to achieve good timing resolution with these devices due to the slow rise time of the aggregated signal for a given light pulse.

SiPMs can have pixel outputs electrically connected by wires attached to the device, or by using short vertical interconnects implemented in Through-Silicon-Via (TSV) technology. Microcells can be connected by traces, and typically one or a few pads per array of microcells (pixel) can be used as output (wire bonds or TSV). An analog SiPM typically requires a front-end electronics to buffer (and/or amplify) the signal from the SiPM for further processing.

The semiconductor wafers on which the SiPM are created have limited space due to their high fill factor requirement. This limited space necessitates that conventional SiPM devices have narrow circuit traces interconnecting the individual microcells to photodetector output. These narrow circuit traces are typically high impedance transmission lines, which have mismatched discontinuities causing a degradation in the pulse characteristics (shape, rise time, and fall time). The degradation can vary between microcells based on position within the photomultiplier array, thus making timing resolution between the detected photon events inaccurate.

### BRIEF DESCRIPTION OF THE DRAWINGS

FIG. 1 depicts a conventional silicon photomultiplier pixel and threshold detector circuitry;

FIG. 2 depicts a configuration for an array of microcells in accordance with embodiments; and

FIG. 3 depicts a side view of a silicon photomultiplier in accordance with embodiments.

### DETAILED DESCRIPTION

Embodying devices and methods provide one or more additional layers in addition to the semiconductor wafer on which the microcells are formed. In accordance with embodiments, these additional layers are formed from material of a lower dielectric constant than the silicon semiconductor wafer. Further, the additional layers can include circuit traces formed from copper transmission lines, which provide a lower impedance for the output pulse from individual microcells.

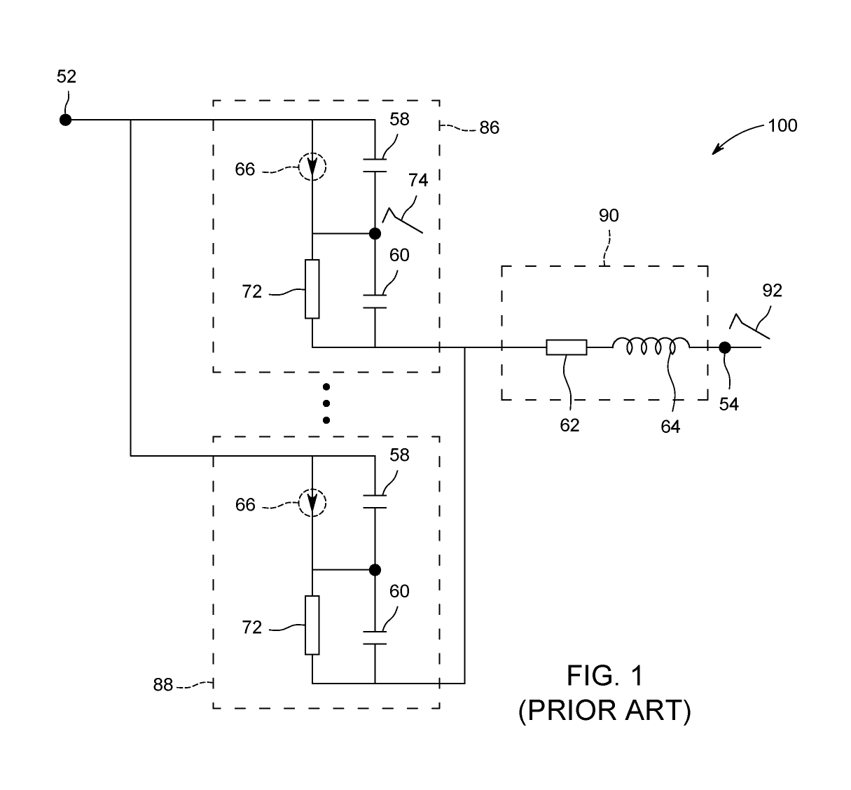

FIG. 1 depicts circuit 100 including a conventional silicon photomultiplier pixel, where a microcell is one of a plurality of microcells 88, 86 within an SiPM array of such cells. In one example, the depicted microcell may be part of an array of single photon avalanche diodes (SPAD) operated in Geiger mode within an analog SiPM. In the depicted example, the model has an associated cathode 52 and anode 54. The microcell portion of the model includes a diode capacitor 58 and a current source 66, such as may be associated with a photodiode. Quench circuitry in the depicted example includes quench resistor 72 and parasitic quench capacitor 60. Downstream of the quench circuitry, in this example, circuit trace impedances 90 are modeled as parasitic resistor 62 and parasitic inductor 64.

In this model each individual APD of a pixel, such as the depicted microcell, is connected to a readout network via the quenching circuitry, including the quenching resistor (Rq) 72 with typical values between about 100 kΩ to about 1 MΩ. When a detected photon generates an avalanche event, a current pulse 74 is generated and the microcell diode capacitance (Cd) 58 discharges down to the breakdown voltage and the recharging current creates a measureable output signal. The typical pulse shape 92 at anode 54 of a single photo electron (SPE) signal has fast rise time (i.e., a sharp rising edge) followed by a long fall time (i.e., a slow falling tail).

An SiPM pixel can include a plurality of microcells arranged as a matrix, where some of the microcells are closer to the pixel's output port, and others are further from the output port. A distortion/degradation in the pulse shape(s) present at the pixel's output port can be caused by discontinuities and/or impedance mismatches in the trace path for the signal from different constituent microcells of the array. The discontinuities and/or impedance mismatches can be a result of junctions in the circuit traces where the output ports of each microcell connects to the circuit trace; line width variations in the interconnecting circuit traces on the semiconductor wafer, which result in a variation in the transmission line impedances; mismatches between the circuit trace impedance and the pixel output port, and/or the device to which the output port connects.

The geometrical positions of the individual microcells of the SiPM pixel array provide various circuit trace path lengths traveled by each pulse between its microcell and the array output. As the array becomes larger (e.g., about 4×4 mm, or larger), the pulse shape distortion becomes worse due to reflections caused by impedance mismatch, which leads to a degradation in timing resolution between the photon events being detected.

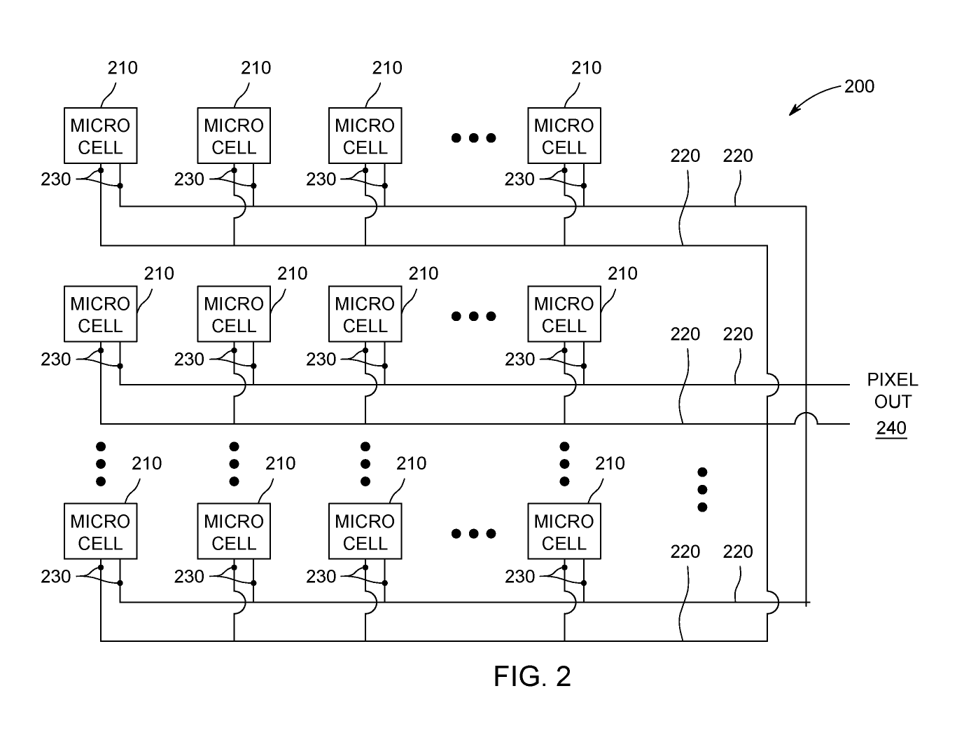

FIG. 2 depicts a configuration for a microcell array in a SiPM pixel 200 in accordance with embodiments. Microcells 210 are arranged in columns, where adjacent microcells can be summed to readout lines formed from circuit path traces 220. The readout lines provide pixel output 240 from the SiPM array. The geometry and position of the microcell locations within array 200 introduce different trace path lengths (with commensurate discontinuities and/or impedance mismatches) to the signals from each of the microcells. Pixel output 240 readout lines can be connected to a summer (not shown). The path length from the respective readout lines to the summer input introduce another level of path length which could differ for each readout line. In conventional SiPM pixels, these differences in path length and the circuit trace paths present variation in the circuit trace impedances seen by each microcell that impact both output signal propagation, and pulse shape characteristics due to the different load impedances seen by the microcells.

In accordance with embodiments, output signals from each microcell 210 are coupled to respective through-silicon-via (TSV) 230 that are at respective microcell 210 outputs. Through-silicon-vias are etched through the bulk of the Si wafer, and provide connection from the active face of the wafer to the back surface of the wafer. The TSVs couple the microcell output signal from the active surface of the semiconductor substrate on which the microcells are formed to the back surface of the wafer. In accordance with embodiments, circuit path traces 220 are formed on this second surface, where there is ample space to produce low impedance traces.

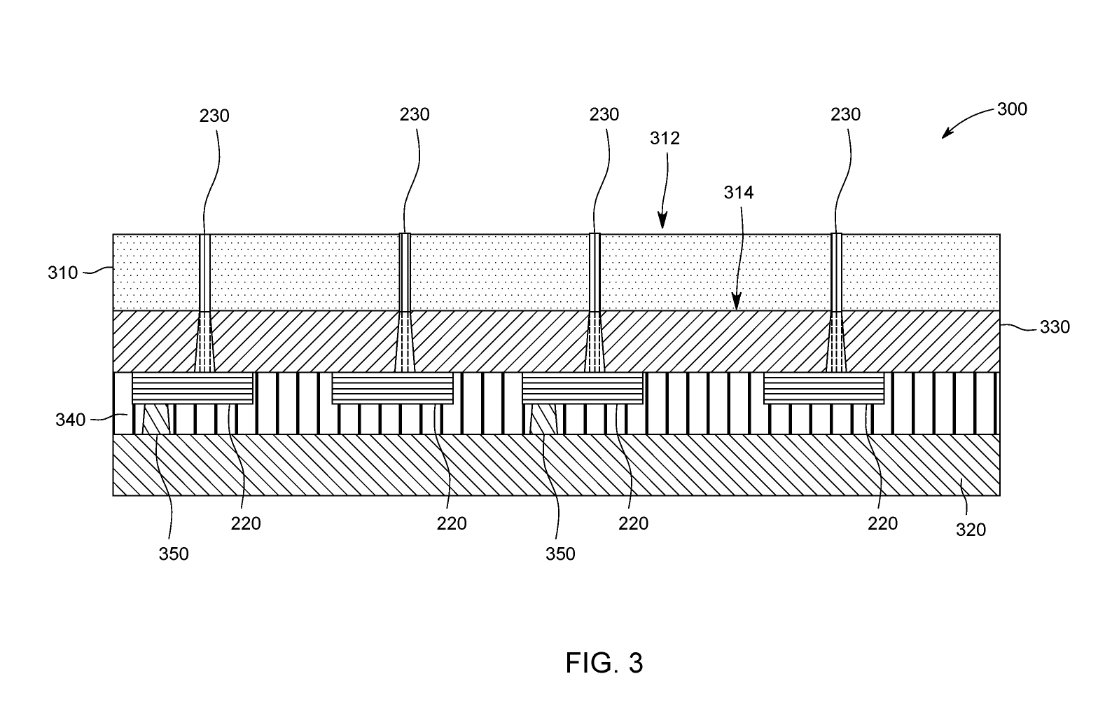

FIG. 3 depicts a side view of SiPM array 300 in accordance with embodiments. SiPM array 300 includes semiconductor wafer 310 and printed circuit board (PCB) 320, which may include a ground plane layer. Semiconductor wafer 310 includes a first (active) surface 312, and a second (back) surface 314 located opposing the first surface. The active semiconductor wafer surface has devices (i.e., microcells) which are exposed to impinging photons. In some implementations, printed circuit board (PCB) 320 can be a metal clad printed circuit board (MCPCB).

SiPM array 300 also includes one or more dielectric (repatterning) layer 330 on which are circuit traces 220. PCB 320 can interface with circuit traces 220 through openings 350 in a second organic dielectric layer 340. The respective outputs of microcells on semiconductor wafer 310 are connected to respective circuit trace(s) 220 on dielectric layer 330 by respective TSV(s) 230.

The routing layers (i.e., circuit traces 220) on dielectric layer 330 can be formed by applying die repatterning techniques. In some implementations, the dielectric layer can include polymers (e.g., polyimides), which are applied on the semiconductor wafer in liquid form. Then the wafer can be spun at high revolution to achieve a uniform thickness for the dielectric layer, and subsequently cured. The TSVs can be formed using photolithographic patterning and dry-etching processes. The routing layers themselves can be formed on the cured dielectric layer by evaporation deposition and photolithography.

Embodying SiPMs and/or PET detectors have several advantages over conventional SiPMs and/or PET detectors formed by conventional silicon wafer fabrication processes. Polyimide has a lower dielectric constant than the conventional silicon oxide (SiO₂)—e.g., about 3.0-3.2 versus 3.8. Also, the polyimide can be deposited in significantly thicker, lower stress films than are available for SiO₂ deposition.

The conductor material for circuit traces 220 on dielectric layer 330 can be formed from copper (Cu), nickel (Ni), and/or gold (Au). The thickness of a copper circuit trace on dielectric layer 330 can be in the range of about less than 1 micron to about greater than 10 microns. In contrast, the conventional wafer production process provides traces of less than 1 micron thick. The thickness of embodying circuit traces 220 can be dependent on the layout complexity and the number of routing channels being provided—which can be dependent on the M×N matrix size of the underlying SiPM pixel. Further, aluminum has an electrical resistivity (2.65 μΩ·cm) that is about 60% higher than Cu (1.67 μΩ·cm).

In accordance with embodiments, circuit trace 220 transmission lines formed using die repatterning materials and processes improve the signal characteristics of pulse output waveforms from the microcells. This improvement is due to the lower resistivity of embodying circuit traces 220, which is not available in conventional SiPM pixels, along with lower capacitive terms (from the lower dielectric constant of dielectric layer 330), which is also not available in conventional SiPM pixels.

Conventional SiPM devices can provide circuit trace routing above the plane of the SPAD. Such routing necessarily must take into account that the circuit traces themselves can block photons from reaching the active silicon surface. As a result, these circuit traces are narrow, and routed around the perimeters of the active devices above the active surface of the wafer. Neither the length nor width of the traces can be optimized for signal quality. Die repatterning is conventionally implemented to reconfigure a perimeter ring of I/O lines for an area array. These devices, and the I/O lines, are typically insensitive to routing parasitics.

Conventional approaches to optimizing SiPM circuits are bounded by materials and processes used in device fabrication. Dielectric layers are typically silicon dioxide (SiO₂) or silicon nitride (SiN) and of limited thickness due to mechanical stresses. Copper circuitry is rarely deposited on the silicon wafer because of the known issue of copper contamination of the silicon.

Embodying devices include TSVs, and one or more repatterning layers on the back surface of the silicon layer (i.e., the silicon layer surface opposing its active front surface). Accordingly, the entire surface area of the embodying SiPM is available for routing the circuit traces and optimizing the path impedances. Additionally, alternate materials can be used to minimize parasitics as well. Embodying devices implement die repatterning to solve the problem of signal degradation in conventional SiPM devices due to routing parasitics.

Although specific hardware and methods have been described herein, note that any number of other configurations may be provided in accordance with embodiments of the invention. Thus, while there have been shown, described, and pointed out fundamental novel features of the invention, it will be understood that various omissions, substitutions, and changes in the form and details of the illustrated embodiments, and in their operation, may be made by those skilled in the art without departing from the spirit and scope of the invention. Substitutions of elements from one embodiment to another are also fully intended and contemplated. The invention is defined solely with regard to the claims appended hereto, and equivalents of the recitations therein.

1. A silicon photomultiplier array comprising:
a plurality of microcells within the photomultiplier array and located on a silicon wafer, the plurality of microcells arranged in rows and columns;
each of the plurality of microcells including an output port, and configured to provide a pulse waveform having pulse characteristics;
at least one repatterning dielectric layer in contact with a silicon wafer layer back surface, the silicon wafer having an active surface opposed to the back surface; and
a plurality of respective through-silicon-vias (TSVs) coupling the output port of respective ones of the plurality of microcells on the active surface of the silicon wafer to a plurality of respective circuit traces on the at least one repatterning dielectric layer disposed on the back surface of the silicon wafer.

2. The silicon photomultiplier array of claim 1, including the circuit traces constructed as transmission lines.

3. The silicon photomultiplier array of claim 1, including a ground plane layer adjoining the at least one repatterning layer.

4. The silicon photomultiplier array of claim 1, the dielectric layer including a polyimide.

5. The silicon photomultiplier array of claim 1, the circuit traces including substantially one of copper, nickel, and gold.

6. A method of producing a silicon photomultiplier array, the method comprising:
producing a plurality of microcells within the photomultiplier array and located on the silicon wafer, the plurality of microcells arranged in rows and columns;
forming at least one repatterning dielectric layer on the back surface of the silicon wafer, the back surface opposed to the active surface of the silicon wafer; and
creating a plurality of respective through-silicon-vias (TSVs) coupling the output port of respective ones of the plurality of microcells to a plurality of respective circuit traces on the at least one dielectric repatterning layer.

7. The method of claim 6, including applying a die repatterning technique to create the dielectric surface.

8. The method of claim 7, the die repatterning technique including applying a liquid polyimide.

9. The method of claim 6, including performing one of a photolithographic patterning process and a dry-etching process to produce the TSVs.

10. The method of claim 6, each of the plurality of respective circuit traces having a thickness in the range of about less than 1 micron to about greater than 10 microns.

11. The method of claim 6, including forming the plurality of circuit traces by one of an evaporation deposition process and a photolithography process.
